(19) United States
(12) Patent Application Publication
(10) Pub. No.: US 2026/0353653 A1
(43) Pub. Date: Nov. 5, 2026

(54) COST-EFFECTIVE ROM FOR DIFFERENT CUSTOMERS

(71) Applicant: TEXAS INSTRUMENTS INCORPORATED, Dallas, TX (US)

(72) Inventors: Anija Mohan, Bengaluru (IN); Akhila Ambili Padmakumar, Bengaluru (IN)

(21) Appl. No.: 19/194,353

(22) Filed: Apr. 30, 2025

(51) Int. Cl. H10B 20/00

(52) U.S. Cl. CPC H10B 20/387

(57) ABSTRACT

A first photomask set is used to form a first ROM to store a first bit in the first ROM. The first photomask set includes a first metal mask to form a first set of conductive features in a metal layer at a first layer level in the first ROM. A second photomask set is used to form a second ROM to store a second bit in the second ROM. The second photomask set includes a second metal mask to form a second set of conductive features in a metal layer at the first layer level in the second ROM. The second set of conductive features differs from the first set of conductive features. The difference between the first set of conductive features and the second set of conductive features is solely responsible for a difference between the first bit and the second bit.

### BACKGROUND

Read-only memory (ROM) is a type of non-volatile memory used in computers and other electronic devices. Data stored in ROM cannot be electronically modified. ROM is useful for storing software, such as boot code or firmware, which is rarely if ever changed during the life of the system.

### SUMMARY

Some examples relate to a method. In this method, a first photomask is used set to form a first read-only memory (ROM) on a first substrate so as to store a first bit in the first ROM. The first photomask set includes a first metal mask used to form a first set of conductive features in a metal layer at a first layer level relative to the first substrate. A second photomask set is used to form a second ROM on a second substrate so as to store a second bit differing from the first bit in the second ROM. The second photomask set includes a second metal mask used to form a second set of conductive features in a metal layer at the first layer level relative to the second substrate. The second set of conductive features is formed by the second metal mask and differs from the first set of conductive features formed by the first metal mask. The difference between the first set of conductive features formed by the first metal mask and the second set of conductive features formed by second metal mask is solely responsible for the difference between the first bit stored in the first ROM and the second bit stored in the second ROM.

Other examples relate to a plurality of integrated circuits. These integrated circuits include a first read-only memory (ROM) on a first substrate, and a second ROM on a second substrate. The first ROM stores a first pattern of bits, and the second ROM stores a second pattern of bits that differs from the first pattern of bits. The first ROM includes a first pattern of active area regions, a first pattern of gate electrodes, a first pattern of contacts, and a first pattern of conductive features in a metal layer. The second ROM includes a second pattern of active area regions, a second pattern of gate electrodes, a second pattern of contacts, and a second pattern of conductive features in a metal layer. The first pattern of active area regions is the same as the second pattern of active area regions, the first pattern of gate electrodes is the same as the second pattern of gate electrodes, the first pattern of contacts is the same as the second pattern of contacts, and the first pattern of conductive features in the metal layer over the first substrate differs from the second pattern of conductive features in the metal layer over the second substrate.

Other examples relate to a system including an array of read only memory (ROM) cells in which the ROM cells are arranged in rows that each extend in a first direction and columns that each extend in a second direction over a substrate. The rows and the columns intersect one another at respective intersection locations and each intersection location includes a ROM cell. Each ROM cell includes an access transistor having a first terminal, a second terminal, and a gate terminal. A plurality of contacts are disposed within the array of ROM cells, wherein each first terminal and each second terminal of each access transistor includes a contact coupled thereto; and a metal layer is disposed over the plurality of contacts and includes a plurality of reference line structures and a plurality of bit-line structures that extend generally in the second direction over the array of ROM cells. Each of the plurality of reference line structures is coupled to a corresponding contact of the plurality of contacts and each of the plurality of bit-line structures of the metal layer is coupled to a corresponding contact of the plurality of contacts.

Other examples relate to a system. The system includes an array of read only memory (ROM) cells in which the ROM cells are arranged in rows each extending in a first direction and columns each extending in a second direction over a substrate. The rows and the columns intersect one another at respective intersection locations and each intersection location includes a ROM cell of the array. Each ROM cell includes an access transistor having a first terminal, a second terminal, and a control terminal. A plurality of word-lines extend along the respective rows, wherein a word-line associated with a row of ROM cells is coupled to the control terminals of the access transistors of the row of ROM cells. A plurality of bit-lines extend along the respective columns. A reference line extends along a first column of ROM cells and is arranged between nearest neighboring bit-lines. The first column of ROM cells stores a first digital state in a first ROM cell and a second digital state in a second ROM cell. The access transistor of the first ROM cell includes a first terminal and a second terminal both coupled to the reference line or both coupled to a first bit-line of the plurality of bit-lines.

### BRIEF DESCRIPTION OF THE DRAWINGS

FIG. 1 shows flow chart of a method of programming ROM according to some examples.

FIG. 2 shows a schematic diagram of a ROM configured to store a first bit pattern according to some examples.

FIG. 3 shows a top layout view of a ROM consistent with FIG. 2's schematic diagram.

FIG. 4 shows a cross-sectional view consistent with the layout view of the ROM shown in FIG. 3.

FIG. 5 shows a schematic diagram of a ROM configured to store a second bit pattern according to some examples.

FIG. 6 shows a top layout view of a ROM consistent with FIG. 5's schematic diagram.

FIG. 7 shows a flow chart of a method of manufacturing first and second ROM devices with different bit patterns according to some examples.

FIGS. 8-15 show a series of top layout views that collectively illustrate a method consistent with FIG. 7's flow chart.

FIG. 16 shows a schematic diagram of another ROM.

FIG. 17 shows top layout view of a ROM consistent with FIG. 16's schematic diagram.

FIG. 18 shows a cross-sectional diagram consistent with FIG. 17's top layout view.

FIG. 19 shows a schematic view of another ROM.

FIG. 20 shows top layout view of a ROM consistent with FIG. 19's schematic diagram.

FIG. 21 shows a cross-sectional view consistent with FIG. 20's top layout view.

FIG. 22 shows a block diagram of a system including a ROM array according to some examples of the present disclosure.

### DETAILED DESCRIPTION

A processor chip can include processor logic and ROM, as well as other circuitry, on a single die. Semiconductor manufacturers can tailor these processor chips to meet the demands of various customers. While the processor logic can be logically identical for all the processor chips of the various customers, the customers often desire their own unique data be stored in the ROM of their chips. For example, in the mobile phone technology area, chipsets are made for a first mobile phone service provider to enable phones for the first mobile phone service provider to securely access the mobile network of the first mobile phone service provider. In contrast, chipsets are made for a second mobile phone service provider to enable phones for the second mobile phone service provider to securely access the mobile network of the second mobile phone service provider. To enable this functionality, the only and/or a primary difference between the chipsets is that the boot code stored in ROM of the first mobile phone has a first bit-pattern, and the boot code stored in ROM of the second mobile phone has a second bit-pattern that differs from the first bit-pattern. The first and second bit-patterns cause the first and second phones to execute different instructions/commands when booting up or accessing the mobile networks, and therefore enable the service providers to ensure only authenticated/registered phones can access their respective mobile networks. Thus, semiconductor manufacturers manufacture the ROMs of the chipsets to store different bit-patterns to enable desired network functionality. Semiconductor manufacturers also store different bit-patterns in ROM for automotive devices, industrial devices, and many others.

When semiconductor manufacturers manufacture these chips, the chips include tens or hundreds of layers formed on a semiconductor substrate. These layers are patterned using photolithography techniques. In particular, a layer is patterned using its own photomask, such as a reticle or other photomask, such that tens or perhaps hundreds of photomasks (collectively referred to as a “photomask set”) are needed to produce the final chips. Each photomask can, for example, include a quartz or other transparent plate, and an absorber or light-shielding layer such as chromium or molybdenum silicon (MoSi) disposed on the transparent plate. Then, during manufacturing, each photomask is aligned within an optical path of a scanner or stepper, and light is passed through the photomask to transfer a pattern from the photomask to a photoresist layer on a substrate. In modern semiconductor fabrication, each photomask mask is expensive, with an individual photomask costing tens of thousands or hundreds of thousands of dollars, and an entire photomask set ranging from several hundreds of thousands into the millions of dollars. Some approaches for storing different bit-patterns in ROM require re-design of multiple photomasks used to make those chips. For example, some approaches require different chipsets to use different contact photomasks and different active area photomasks to provide chips with different ROM bit patterns. Because photomasks are expensive, some aspects of the present disclosure appreciate that these other approaches, which require changes to multiple photomasks to program ROM bit patterns in customer chips, are less than optimal.

Therefore, some aspects of the present disclosure allow semiconductor manufacturers to manufacture chipsets with different ROM bit patterns by changing only a single photomask of a photomask set. Thus, all other photomasks can remain the same for chips of different customers, and the ROM bit pattern can be changed for chips of different customers by changing only a single photomask. For example, an active area photomask, a gate photomask, and a contact photomask can each be re-used for different chips for different customers, and only a metal1 photomask can be changed to change the ROM bit pattern on those chips for different customers. Thus, some aspects of the present disclosure make chips with different ROM bit patterns while maximizing re-use of the same photomask set. This provides cost savings compared to other approaches that use multiple different photomasks.

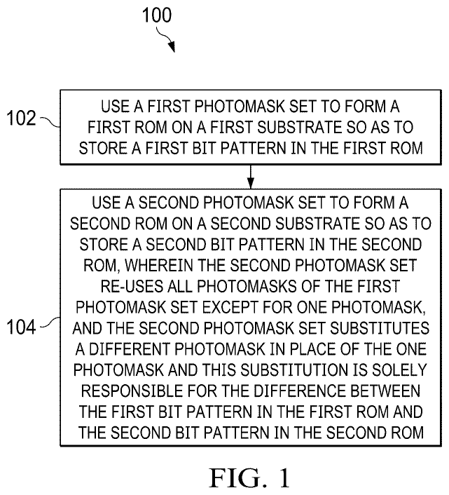

FIG. 1 shows an example method 100 in accordance with some aspects of the disclosure. In act 102, a first photomask set is used to form a first ROM on a first substrate so as to store a first bit or bit-pattern in the first ROM. In act 104, a second photomask set is used to form a second ROM on a second substrate so as to store a second bit or second bit-pattern that differs from the first bit or first bit-pattern in the second ROM. The second photomask set re-uses all photomasks of the first photomask set except for one photomask. Thus, the second photomask set substitutes a different photomask in place of the one photomask and this substitution is solely responsible for the difference between the first bit or bit pattern in the first ROM and the second bit or bit pattern in the second ROM. Aside from this difference/substitution of this one photomask, which is illustrated further herein as a metal1 layer photomask that is changed between the first photomask set used to make a first ROM and the second photomask set used to make a second ROM, all other photomasks are the same for the first photomask set and the second photomask set. Thus, the difference in this one photomask is solely responsible for the difference between the first bit or bit pattern stored in the first ROM and the second bit or bit pattern stored in the second ROM. Further, cost savings increase for photomasks that are higher up the stack, so substituting a metal1 photomask to change the bit or bit-pattern provides more cost savings than substituting an active area mask or contact mask to change the bit or bit-pattern.

Further, if manufacturing process variation is neglected, when the first ROM that was made using the first photomask set is compared to the second ROM that was made using the second photomask set, the first and second ROMs are identical for all layers of the ROMs except for the layer corresponding to the one mask that is different for the two ROMs. For example, if the one photomask is a metal1 photomask, all other layers of the two ROMs are the same as one another except for the metal1 layer. Thus, relative to one another, the two ROMs have the same active areas, the same gate electrodes, the same source/drain regions, the same contacts, the same metal2 layers, the same vias, the same metal3 layers, and so on. The only difference is in the metal1 layers of the two ROMs. This difference in the metal1 layers causes different operable coupling of the various devices such that the first ROM stores a first bit or bit-pattern and the second ROM stores a second, different bit or bit-pattern. This allows manufacturers to program ROM bits or bit patterns for different customers in a very cost-effective manner because it minimizes the number of photomasks that need to be manufactured for the various customers. Although examples are provided herein where a metal1 layer is different for two ROM devices, it will be appreciated that in other examples, other single layers could be alternatively changed. For example, in some other implementations, all layers of two different ROM devices can be the same except for their respective metal2 layers, and their respective metal2 layers can have different conductive patterns that cause the two different ROM devices to have different bit-patterns. Further, in other examples, all layers but a contact layer can be the same, or all layers but an active area layer can be the same, etc.

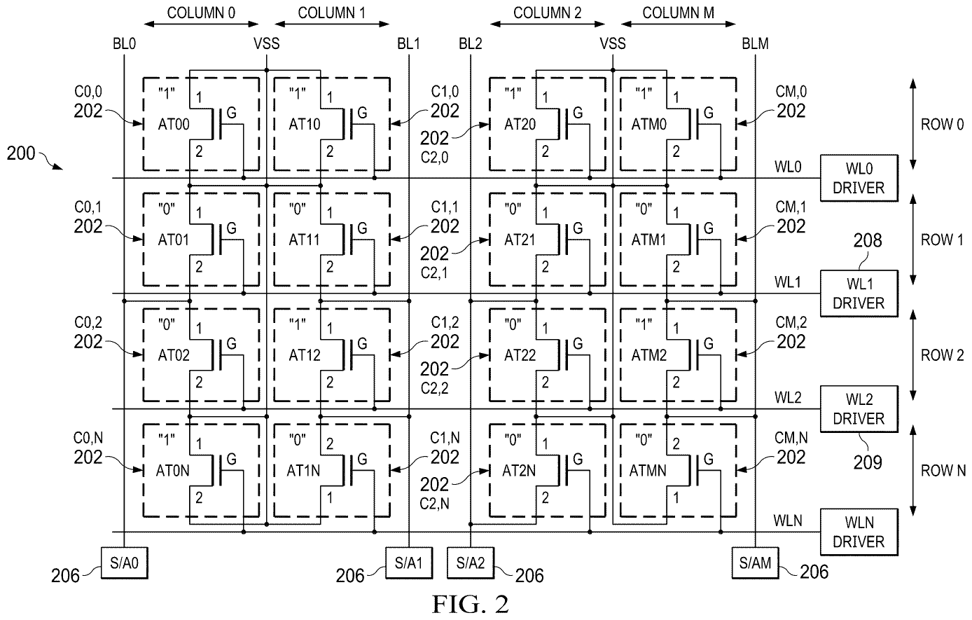

Referring now to FIG. 2, one can see a ROM array 200 in accordance with some examples of the present disclosure. The ROM array 200 includes a number of ROM cells 202 that each store one bit of data. The ROM cells 202 are arranged in M+1 columns (e.g., bits) and N+1 rows (e.g., words), and are indicated as C_{COLUMN}, _{ROW} in FIG. 2. Examples of stored “1” and “0” data states are superimposed over the respective cells in FIG. 2 for convenience, but it will be appreciated that this encoding scheme is arbitrary and the illustrated “1” states and “0” states for the array could alternatively be flipped for the ROM array 200 in other implementations.

Each ROM cell 202 includes a respective access transistor (AT). For example, cell C0,0 includes access transistor AT00; cell C1,0 includes access transistor AT10, and so on. Each access transistor includes first and second terminals (e.g., source and drain terminals, respectively), and a control terminal (e.g., gate terminal). The control terminals (e.g., gates) for each row of access transistors are coupled to a word-line (WL) corresponding to that row. For example, in Row1 of the ROM array 200, the cells C_{0,1} through C_{M,1} form an M bit data word that is accessible by activation of word-line WL1. The first and/or second terminals for each column of access transistors are coupled to a bit-line corresponding to that column, are coupled to a reference line (e.g., VSS) corresponding to that column, and/or are left floating. Sense amplifiers 206 are coupled to the respective bit-lines.

This configuration allows each ROM cell 202 to store a first data state (e.g., logical “0”), or a second data state (e.g., logical “1”). More particularly, each ROM cell that stores a “0” bit has an access transistor whose first terminal is coupled to the reference line (VSS) and second terminal is coupled to a bit-line. See e.g., cells C_{0,1} and C_{1,1}. Thus, for these “0” bits, the access transistor of a ROM cell couples the bit-line of the ROM cell to VSS during a read operation. In contrast, for “1” bits, each ROM cell has an access transistor whose first terminal and second terminal are both coupled to the reference line (VSS) or are both coupled to a bit-line, such that the bit-line is floating during a read operation. See e.g., cells C_{0,0} and C_{1,2}. Thus, when Row1 is accessed by activation of WL1, the accessed ROM cells C_{0,1} through C_{M,1} thereby establish or drive voltage biases and/or charge-levels on bit-lines BL0 through BLM, respectively, so the voltage biases/charge-levels established on the bit-lines represent the data stored in the accessed ROM cells. Generally speaking, while the word-line of one row is asserted to access the cells of the row, the word-lines of the other rows are de-asserted. The sense amplifiers 206 determine the data state from biases/charge on the bit-lines, and latch those data states so they can be output from the ROM device.

During a first read operation when WL1 driver circuit 208 activates word-line WL1 by applying a voltage with a magnitude that is greater than a voltage threshold of the access transistors, each access transistor of Row1 goes into a conductive state, while access transistors of other Rows (Row0 and Row2-RowN) are “off”. Thus, AT01 couples BL0 to VSS, such that S/A-0 206 detects VSS during the first read operation and determines a voltage bias of VSS corresponds to a “0” data state. Similarly, AT11 couples BL1 to VSS such that S/A-1 206 detects a “0” data state during the first read operation, AT21 couples BL2 to VSS such that S/A-2 206 detects a “0” data state during the first read operation, and ATM1 couples BLM to VSS such that S/A-M 206 detects a “0” data state during the first read operation.

During a second read operation when WL2 driver circuit 209 activates word-line WL2 by applying a voltage with a magnitude that is greater than the voltage threshold of the access transistors, each access transistor of Row2 goes into a conductive state, while access transistors of other rows (e.g., Row0, Row1 and Row3-RowN) are “off”. Thus, AT02 couples BL0 to VSS, such that S/A-0 206 detects a “0” data state during the second read operation. AT12 leaves BL1 floating because both the first and second terminals of AT12 are coupled to BL1 under this condition, and S/A-1 206 determines this is a “1” data state. Similarly AT22 couples BL2 to VSS such that S/A-2 206 detects a “0” data state during the second read operation. ATM2 leaves BLM floating because both the first and second terminals of ATM2 are coupled to BLM under this condition, such that S/A-M 206 detects a “1” data state during the second read operation.

As will be appreciated in more detail herein, in some implementations, the ROM array of FIG. 2 allows semiconductor manufacturers to change bit-patterns for ROMs for different customers in a cost effective manner that maximizes re-use of photomasks used during manufacture and limits the need for additional photomasks.

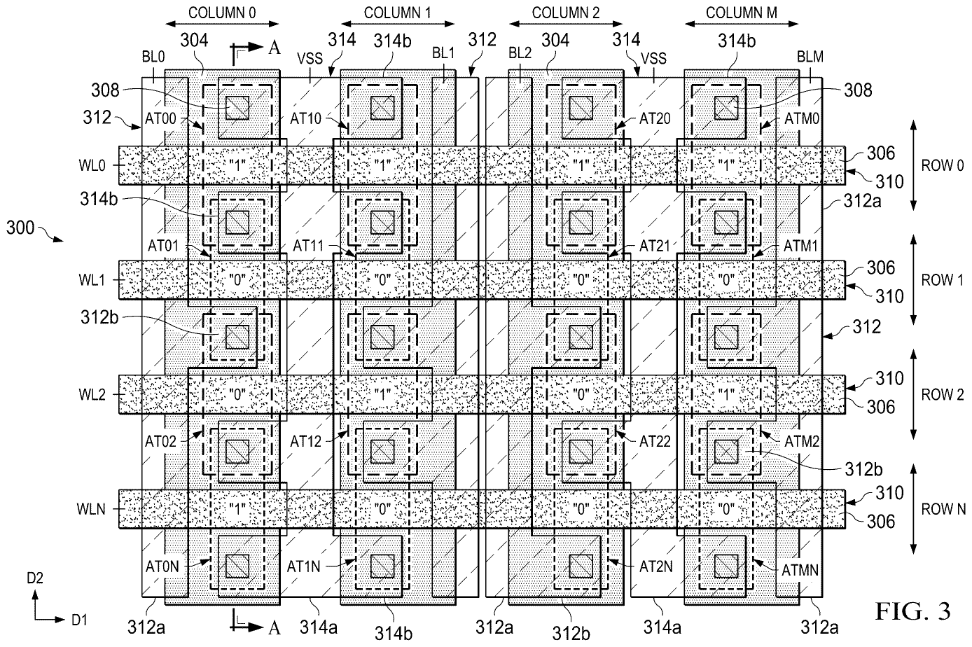

FIG. 3 shows a layout 300 of a memory array that is consistent with FIG. 2's ROM array 200. Within the layout 300, the ROM cells are arranged in N+1 rows (Row0 to Row N) that each extend in a first direction (D1) and M+1 columns (Column0 to ColumnM) that each extend in a second direction (D2) over a semiconductor substrate. The rows and the columns intersect one another at respective intersection locations, and each intersection location includes a ROM cell. Each ROM cell includes an access transistor (AT) having a first terminal (e.g., source), a second terminal (e.g., drain), and a control terminal (e.g., gate). The access transistors are labeled as AT_{COLUMN}, _{ROW} in FIG. 3 to be consistent with FIG. 2. The first and second terminals are doped regions 304 disposed in the substrate, and the gate 306 is a polysilicon or metal line over the substrate. Each doped region 304 of each access transistor includes a contact 308 coupled thereto. For convenience/clarity, only some, but not all, doped region(s) 304, gate(s) 306, and contact(s) 308 are labeled in FIG. 3.

Word-lines 310 (WL0 to WLN) can be made of metal or polysilicon and extend in a linear and continuous manner in the first direction (D1) between gates along respective rows. Bit-line structures 312 (BL0 to BLM) and reference line structures 314 (e.g. VSS lines) extend in the second direction (D2) along respective columns. The bit-line structures 312 and reference line structures 314 are formed in a metal1 layer. Each bit-line structure 312 includes a main bit-line structure 312a extending in the first direction D1, and fingers 312b branching off the main bit-line structure 312a. The fingers 312b of the bit-line structures extend in the second direction D2 to couple to the doped regions 304 of the access transistors via the contacts 308. Each reference line structure 314 similarly includes a main reference line 314a extending in the first direction, and fingers 314 b branching off the main reference line 314a. The fingers 314 b of the reference line structure extend in the second direction D2 to couple to the doped regions 304 of the access transistors via contacts 308. The fingers 314b of the reference line structures extend in opposite directions away from each main reference line 314a, while the fingers 312 b of the bit-line structures extend from one side from each main bit-line structure 312a to be interdigitated with the fingers 314b of the reference line structure. In other examples, the bit-line structures 312 and reference line structure 314 can be swapped from what is illustrated in FIG. 3.

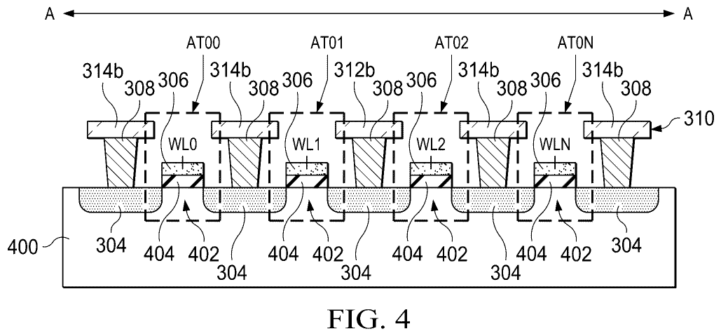

As can be seen in FIG. 4's cross-sectional view, which is taken along line A-A of FIG. 3's layout, the first and second terminals of the access transistors are doped regions 304 disposed in a semiconductor substrate 400. The semiconductor substrate 400 can be a bulk monocrystalline silicon substrate, but can also be a silicon on insulator (SOI) substrate or other semiconductor substrate. The doped regions 304 have a first conductivity type (e.g., n-type) and are common source/drain regions, meaning that they are shared or common between adjacent access transistors. Channel regions 402 having a second conductivity type (e.g., p-type) separate the doped regions 304 of each access transistor from one another. A gate 306 corresponding a word-line is arranged over each channel region 402, and a gate dielectric 404 separates the gate 306 from the channel region 402. Thus, the doped region 304 of one access transistor is common with the doped region 304 of an adjacent access transistor, and a single contact 308 ohmically contacts to each doped regions 304. Having contacts 308 coupled to all of the doped regions 304, respectively, is an advantage in that it “sets up” a foundational underpinning for the metal1 bit-line structure 312 and reference line structures 314 to change the data states of the ROM for various customers solely by changing the conductive patterns in the metal1 layer. Thus, because the doped regions 304 are common source/drains and a contact 308 is coupled to each common source/drain, this arrangement helps enable the desired pattern of “1” and “0” to be stored in the ROM and easily changed by altering only a single photomask (e.g., and only the metal1 layer) for various customers.

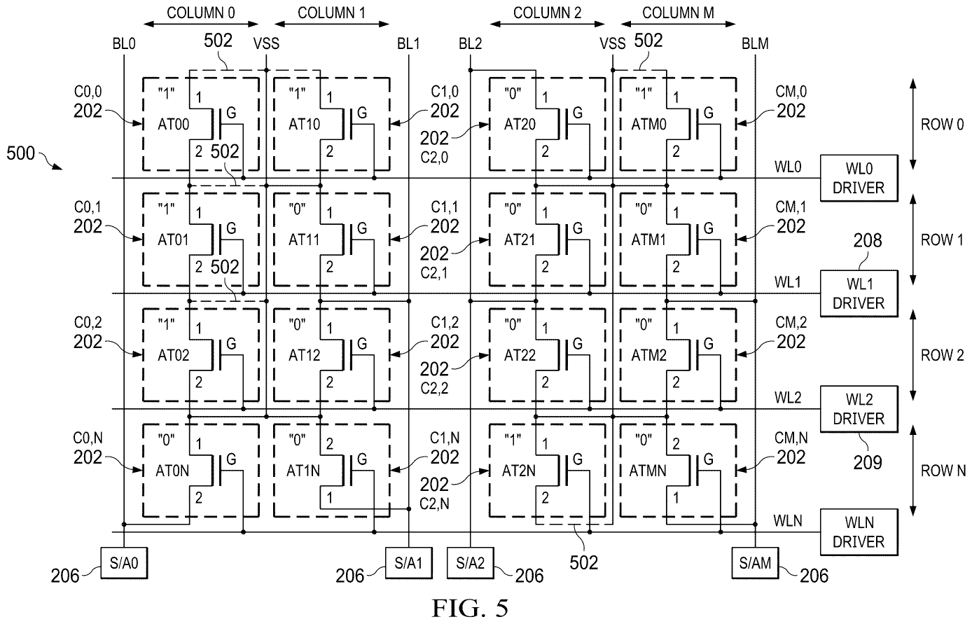

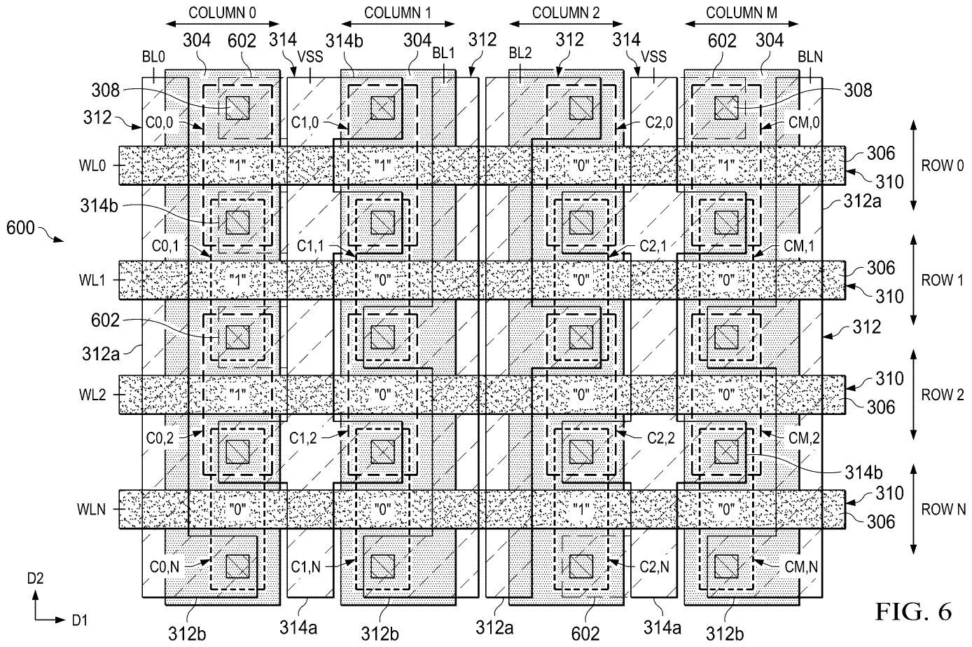

Thus, an advantage of the ROM array 200 and layout 300 of FIGS. 2-4 is that it allows ROM data states to be programmed/changed for different chips by changing only a single photomask (e.g., a metal1 photomask) during manufacture. Notably, when comparing FIGS. 2-4 (in which the first ROM array stores a first bit or bit-pattern) with FIGS. 5-6 (in which the second ROM array stores a second bit or bit-pattern that differs from the first bit or bit-pattern), doped regions 304, gates 306, and contacts 308 are the same for the first ROM array's layout 300 (FIG. 3) and the second ROM array's layout 500 (FIG. 5). The only difference between the first ROM array's layout (FIG. 3) and the second ROM array's layout (FIG. 5) lies in the pattern of conductive features in the metal1 layer 312/314 of those layouts. As such, this difference evidences the fact that these chips were manufactured according to an efficient/streamlined manufacturing process whereby the chips were fabricated using a photomask set that was largely re-used for both chips, except that only a single photomask (e.g., metal1 photomask) was changed was making the chips. Therefore, these chips for these layouts 300, 500 had lower manufacturing costs than other chips with different ROM bits or bit-patterns.

Turning now to FIGS. 5-6, one can see a second ROM array that stores a second bit or bit-pattern with reference to a layout 500 (FIG. 5) and cross-sectional view 600 (FIG. 6). This second ROM array has a different bit or bit-pattern than the first ROM array of FIGS. 2-4. Similar to FIGS. 2-4, for “0” bits in FIGS. 5-6, the access transistor of a ROM cell couples the bit-line of the ROM cell to VSS during a read operation. See e.g., Cells C2,0 and C1,1 in FIG. 5. Also, as in FIGS. 2-4, for “1” bits in FIGS. 5-6, each ROM cell has a bit-line that is floating during a read operation. See e.g., cells C_{0,0} and C_{0,1} in FIG. 5. Further, in addition to the fact that the second ROM in FIGS. 5-6 stores a different bit-pattern than the first ROM in FIGS. 2-4, several of the connections in the schematic of FIG. 5 and metal1 features in the layout of FIG. 6 can optionally be removed, as shown by dashed lines 502 in FIG. 5 and hashed areas 602 in FIG. 6.

Thus, FIGS. 2-3 showed a layout and schematic where a single metal layer (metal 1) contacts each and every contact of the ROM array to determine “1” and “0” data states. However, in FIGS. 5-6, the metal fingers shown by dashed lines 502 in FIG. 5 and corresponding hashed metal1 areas 602 in FIG. 6 are optional because there are source/drains/contacts within a set of consecutive ones data states, so even if these metal fingers 502/602 are omitted as shown or are added in, the result is still that the corresponding bit-line is still floating when accessed by a given word-line. For example, for Cell C_{0,1}, when WL1 is asserted, if the metal fingers 502/602 are in place, BL0 is still floating; whereas if the metal fingers 502/602 are removed, BL0 is still floating. Therefore, while FIGS. 2-4 showed an example where “all” contacts of the entire ROM array are coupled to the metal1 layer, it is to be appreciated that in some alternative examples only “substantially all” contacts of the entire ROM array are coupled to the metal1 layer, and a limited number of contacts may not be coupled to the metal1 layer. In the example of FIG. 5, it is shown by cells C_{0,0}, C_{0,1}, C_{0,2} that when ROM cells for three consecutive rows of a single column have “1” states (or “0” states if the convention for data states was flipped), then any of the contacts for these ROM cells could be spaced apart and isolated from the metal1 layer. Similarly, any ROM cells which are at an upper or lower edge of the ROM array and which have “1” states could have contacts that are spaced apart from and isolated from the metal1 layer. See cells C_{0,0}, C_{1,0}, C_{M,0}, C_{2,N}, and C_{M,N}. The exact number of fingers that can be omitted depend on the bit patterns stored by the ROM cells. In some examples, “substantially all” contacts of the entire array can correspond to more than 90% of the contacts of the entire array being coupled to the metal1 layer, or even more than 95% of the contacts of the entire array being coupled to the metal1 layer.

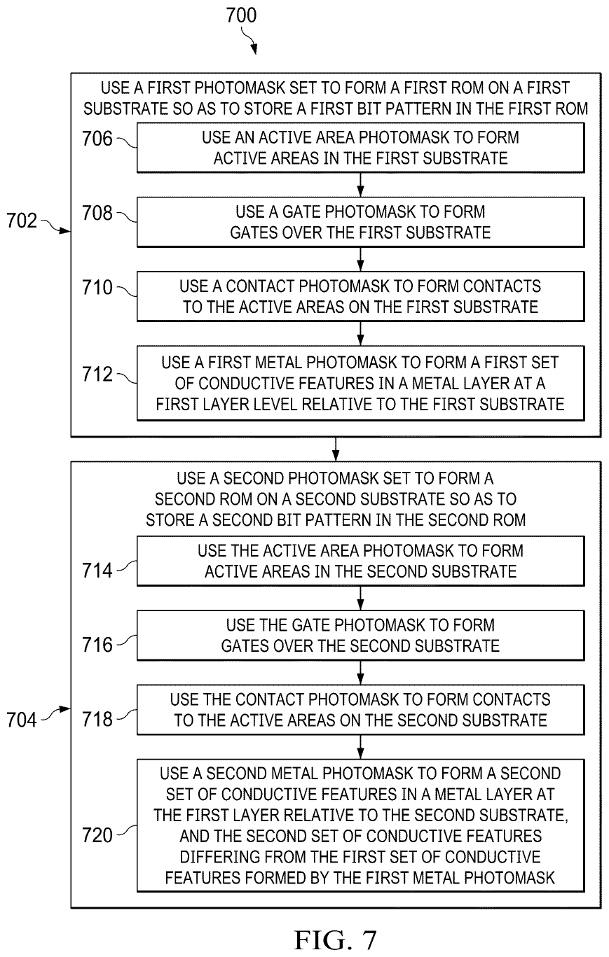

FIG. 7 shows another example of a method 700 in accordance with some aspects of the disclosure. While method 700 and others provided herein may be illustrated and/or described as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

In act 702, a first photomask set is used to form a first read-only memory (ROM) on a first substrate so as to store a first bit or bit-pattern in the first ROM.

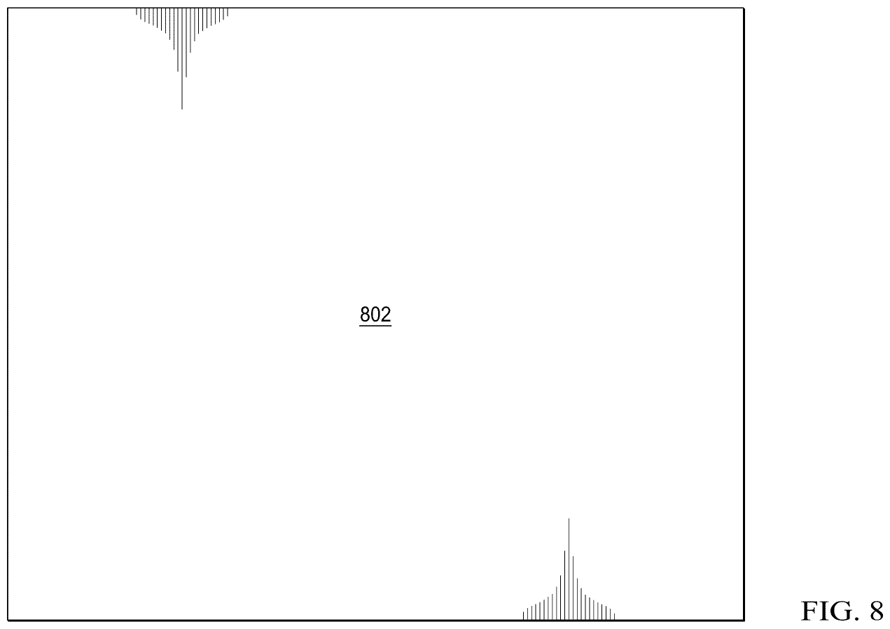

As illustrated in FIG. 7, act 702 can include several acts. At 706, a first substrate is received, and an active area photomask is used to form active areas in the first substrate. The active area photomask includes a transparent plate and an absorber or light-shielding layer. Thus, the active area photomask is positioned within an optical path of a photolithography stepper or scanner, and then light is passed through the active area photomask to transfer a pattern from the active area photomask to a first layer of photoresist on the first substrate. In some instances, an ion implantation is carried out with the patterned first layer of photoresist (and/or another patterned layer beneath the photoresist) to form active areas in the substrate. The active areas can for example be doped regions 802 that correspond to n-wells or p-wells in the substrate, and for example can be consistent with the layout view provided in FIG. 8. The first layer of photoresist is then removed.

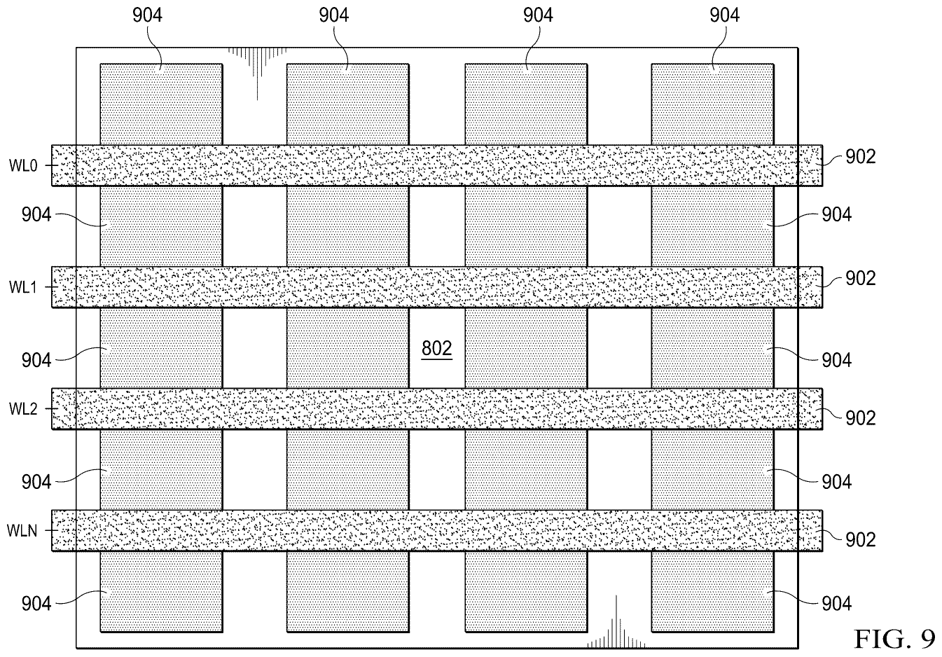

At act 708, a gate photomask is then used to form gates over the active areas of the first substrate. For example, a gate layer such as a polysilicon layer or metal layer is formed on the first substrate over the active areas, and a second layer of photoresist is formed over the gate layer. The gate photomask is positioned within the optical path of the photolithography stepper or scanner after the active area photomask is removed, and then light is passed through the gate photomask to transfer a pattern from the gate photomask to the second layer of photoresist. An etch is then carried out to etch the pattern into the gate layer to form gates 902 over the active areas, and for example can be consistent with the layout view provided in FIG. 9. The second photoresist is then removed. Ion implantation can then be performed to form doped regions 904, such as source/drain regions in the substrate and can be consistent with FIG. 9.

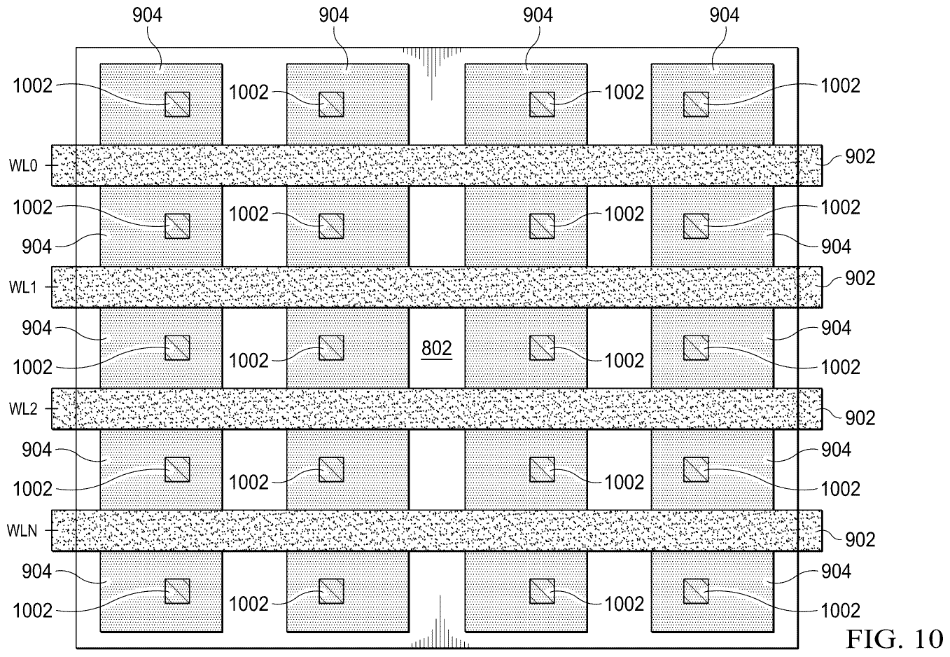

At act 710, a contact photomask is then used to form contacts over the active areas of the first substrate. For example, a first dielectric layer is formed over the gates, and a third layer of photoresist is formed over the first dielectric layer. The contact photomask is positioned within the optical path of the photolithography stepper or scanner after the gate photomask is removed, and then light is passed through the contact photomask to transfer a pattern from the contact photomask to the third layer of photoresist. An etch is then carried out to etch the pattern into the first dielectric layer, and then the third layer of photoresist is removed. A silicide layer and a metal contact layer are then formed, and a chemical mechanical planarization (CMP) or other removal process is used to establish contacts. In some examples, the contacts 1002 can be formed for substantially all of the doped regions over the entire ROM array, and can be consistent with the layout view provided in FIG. 10.

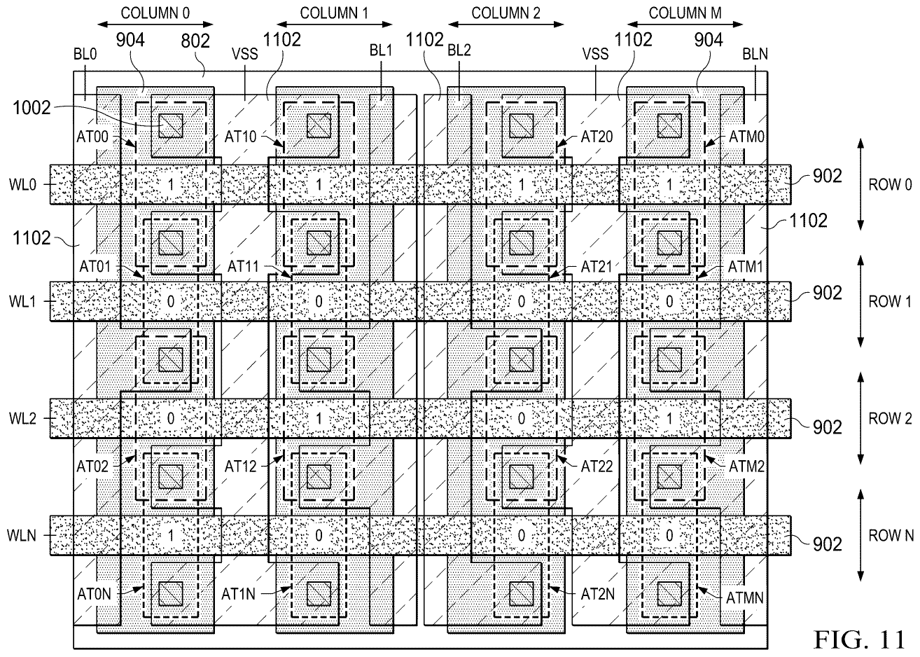

In act 712, a first metal photomask set is used to form a first set of conductive features in a metal layer at a first layer level relative to the first substrate. For example, a second dielectric layer is formed over the contacts, and a fourth layer of photoresist is formed over the second dielectric layer. The first metal photomask is then positioned within the optical path of the photolithography stepper or scanner after the contact photomask is removed, and then light is passed through the first metal photomask to transfer a pattern from the first metal photomask to the fourth layer of photoresist. An etch is then carried out to etch the pattern into the second dielectric layer, and then the fourth layer of photoresist is removed. A first metal layer, which may comprise copper, aluminum, or a copper alloy, is then formed, and a chemical mechanical planarization (CMP) or other removal process is used to establish first metal layer features. In some examples, the first metal layer features 1102 can be consistent with the layout view provided in FIG. 11 and can establish a first bit or first bit-pattern.

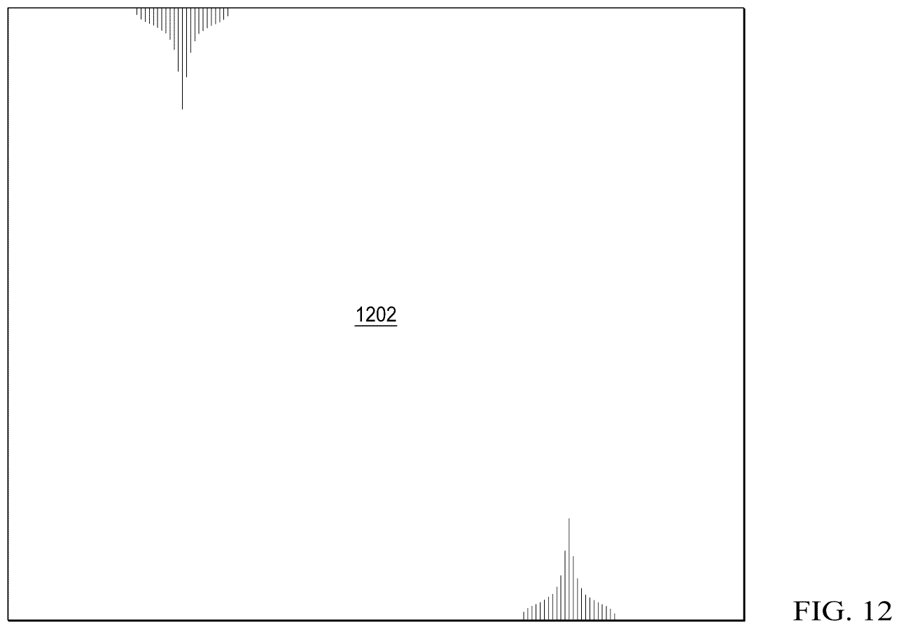

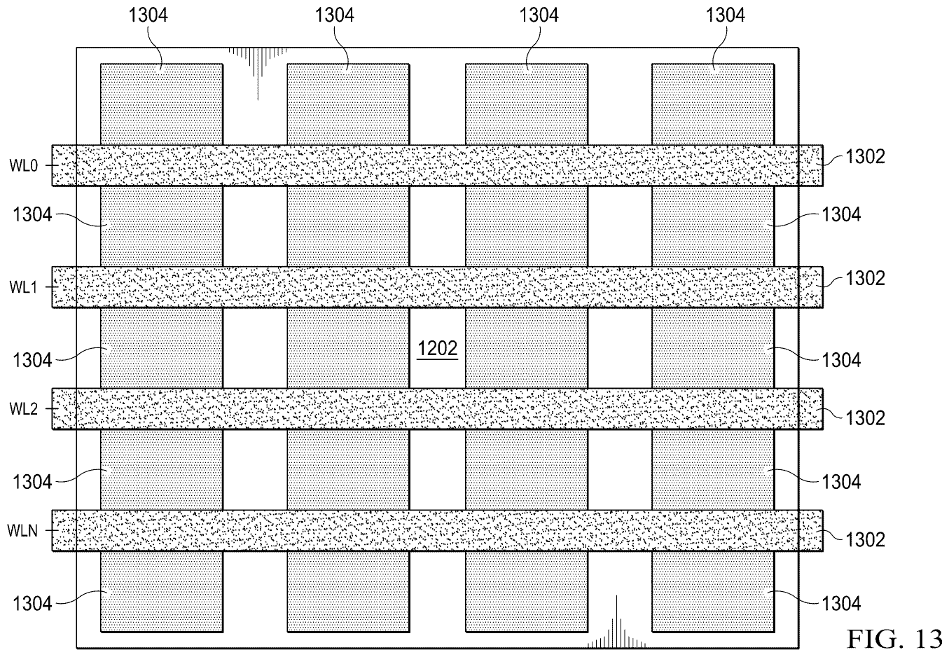

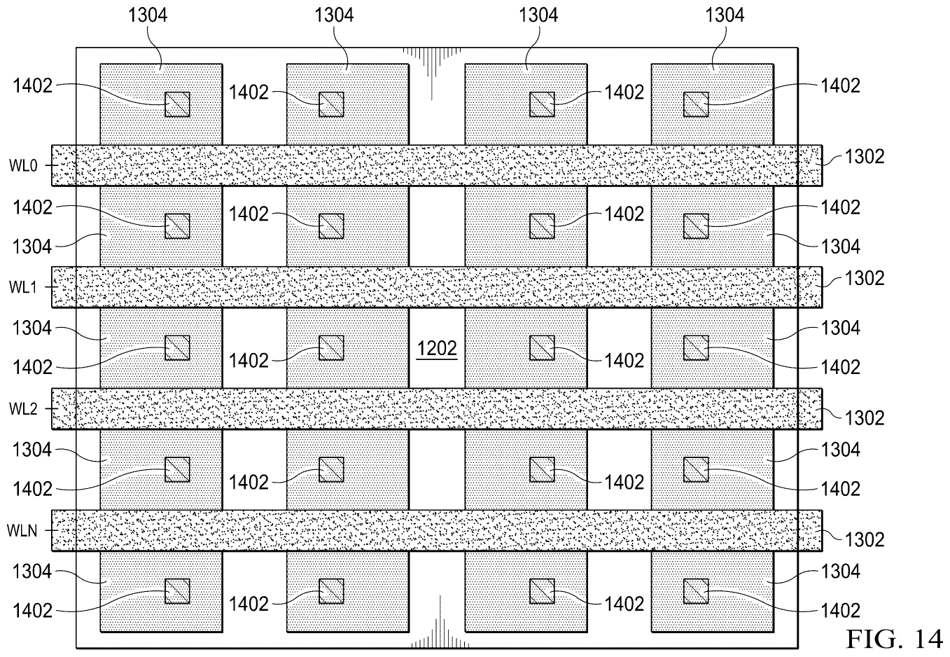

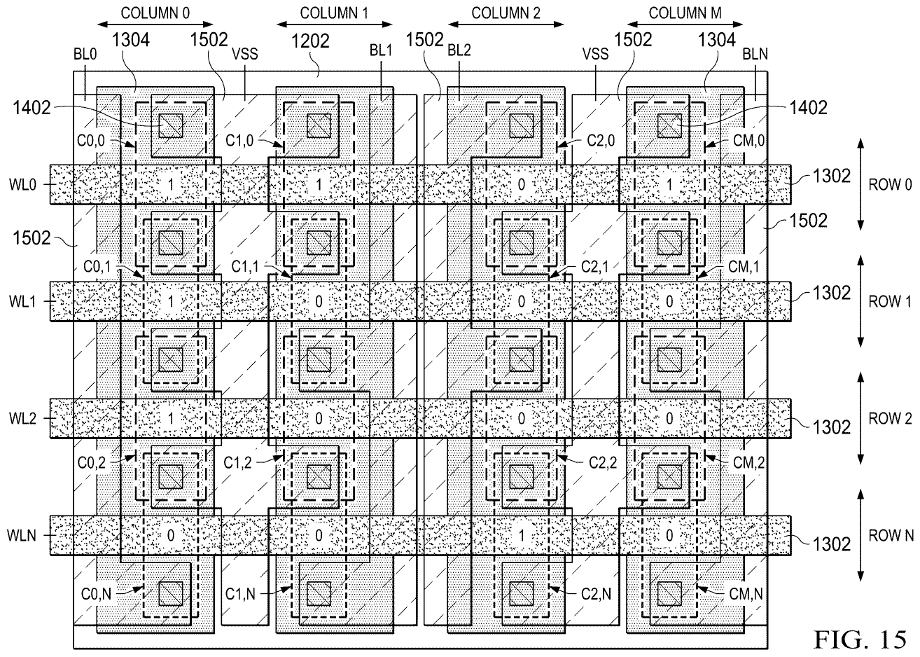

In act 704 of FIG. 7, a second photomask set is used for form a second ROM on a second substrate so as to store a second bit or bit-pattern in the second ROM. The second photomask used in act 704 set re-uses all photomasks of the first photomask set used in act 702 except for one photomask. Thus, in FIG. 7's illustrated example, the active area photomask used in act 706 is re-used in act 714 to produce active areas 1202 in the second substrate such as shown in FIG. 12; the gate photomask used in act 708 is re-used in act 716 to produce gates 1302 and doped regions 1304 over the second substrate such as shown in FIG. 13; and the contact photomask used in act 712 is re-used in act 718 to produce contacts 1402 on the second substrate such as shown in FIG. 14. However, the metal1 mask used in act 720 is different from the metal1 mask used in act 712, such that this substitution of the one metal1 mask used in act 720 for the previous metal1 mask used in act 712 is solely responsible for the difference between the first bit or bit pattern in the first ROM on the first substrate and the second bit or bit pattern in the second ROM on the second substrate. Thus, FIG. 15 shows an example where a second metal1 mask has been used to form a second ROM on the second substrate, and the conducive features 1502 of the metal1 layer formed using the second metal1 mask on the second substrate give rise to second bit pattern for the second ROM. Aside from this difference/substitution of this one photomask, all other photomasks are the same for the first photomask set (and first ROM) and the second photomask set (and second ROM). Therefore, the method of FIG. 7 is advantageous in that it provides a cost effective way for a semiconductor manufacturer to customize bit-patterns for ROM while maximizing re-use of photomasks.

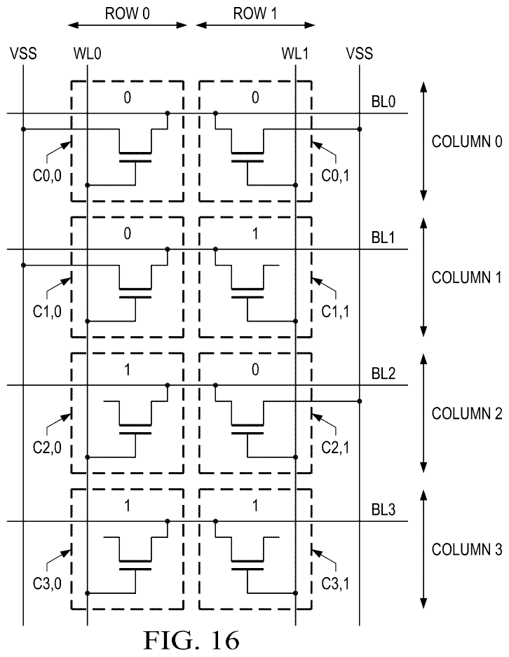

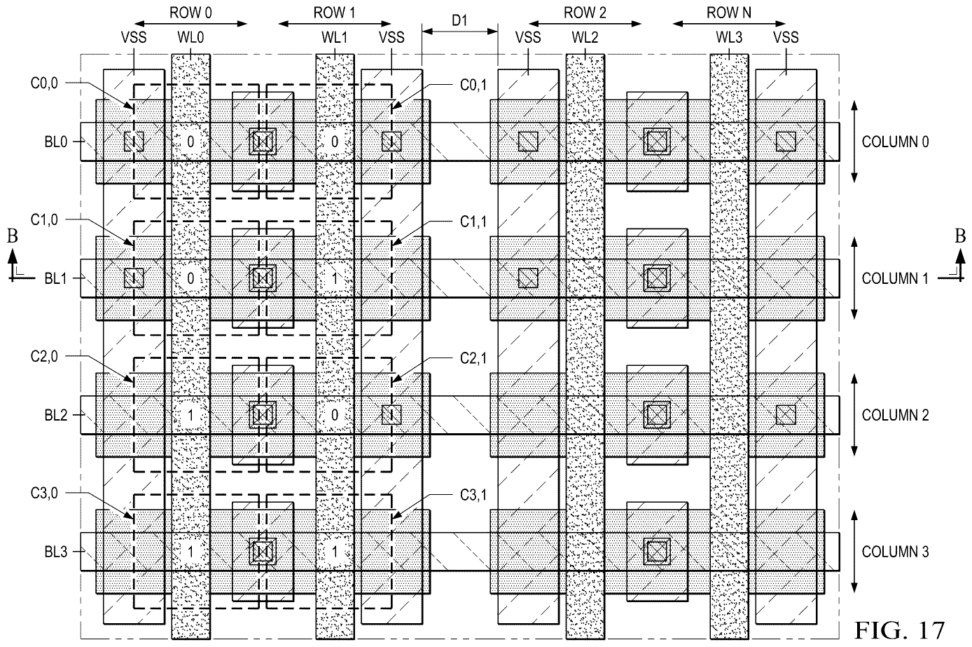

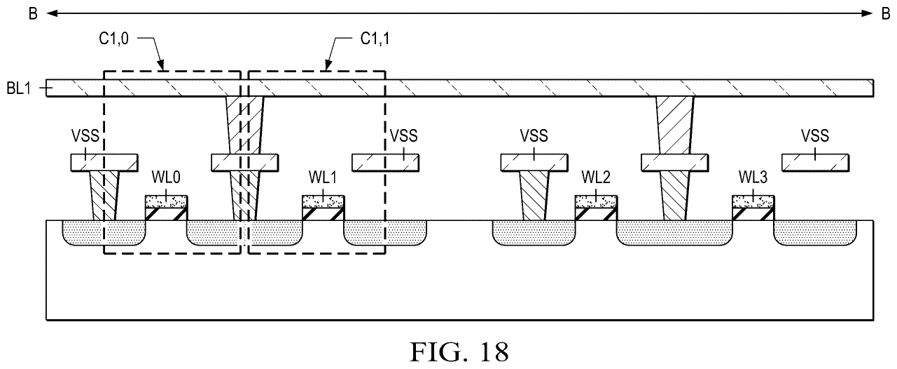

FIG. 16 provides a schematic for another ROM device. FIG. 17 provides a layout that is consistent with FIG. 16's ROM device, and FIG. 18 provides a cross-sectional view consistent with FIG. 17's layout. In FIGS. 16-18, each ROM cell again includes an access transistor, and stores either a “0” bit or a “1” bit. Respective word-lines are coupled to gates of respective access transistors along respective rows, and respective bit-lines are coupled to drain regions of the access transistors along respective columns. For cells that store a “0” bit, their access transistors have a source terminal coupled to VSS. See e.g., cells C_{0,0} and C_{0,1}. In contrast, for cells that store a “1” it, their access transistors have a drain terminal that is floating and “disconnected” from the corresponding bit-line of the column. See e.g., cells C_{1,1} and C_{2,0}. In the layout view of FIG. 17, this “disconnection” is achieved by omitting a contact in the layout. Thus, this is another example where a ROM bit or bit-pattern can be changed by only changing a single photomask-here, a contact photomask is the only photomask that is changed. However, the previous examples of FIGS. 2-4, and 5-6, and 7-15, which change only a metal1 photomask still offer an advantage in that they are cheaper to produce than the examples of FIGS. 16-17, due to the fact that cost savings increase for photomasks that are higher up the stack. Therefore, substituting a metal1 photomask to change the bit or bit-pattern (as in FIGS. 2-4, and 5-6, and 7-15) provides more cost savings than substituting a contact mask to change the bit or bit-pattern (as in FIGS. 16-17), though both are still viable solutions.

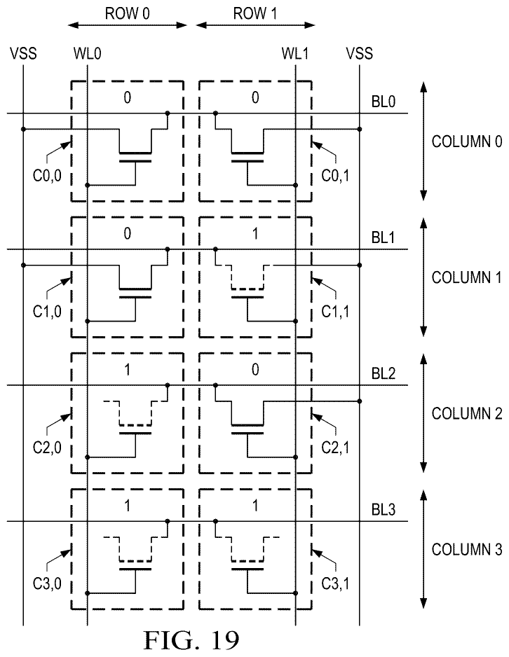

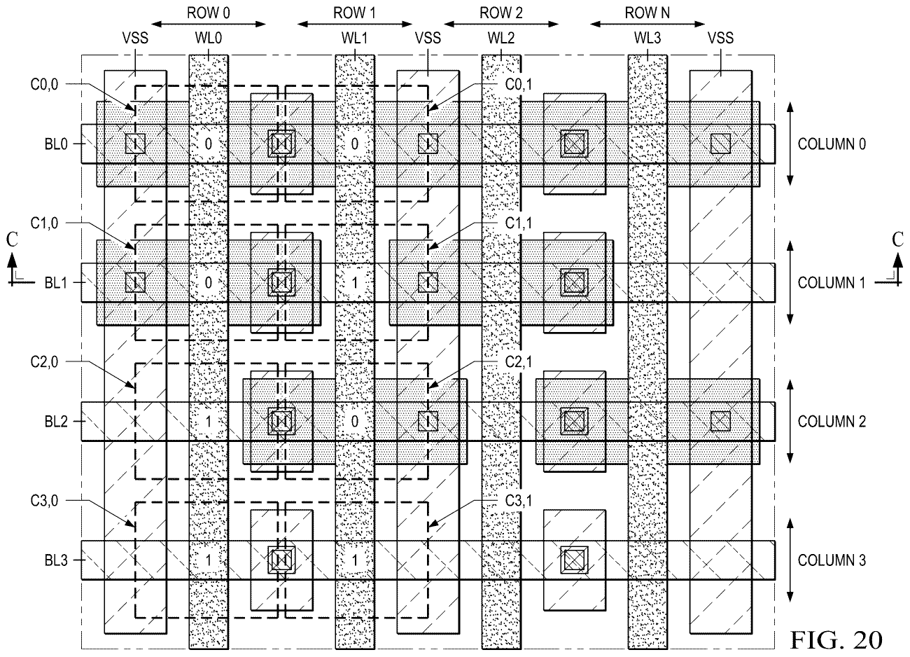

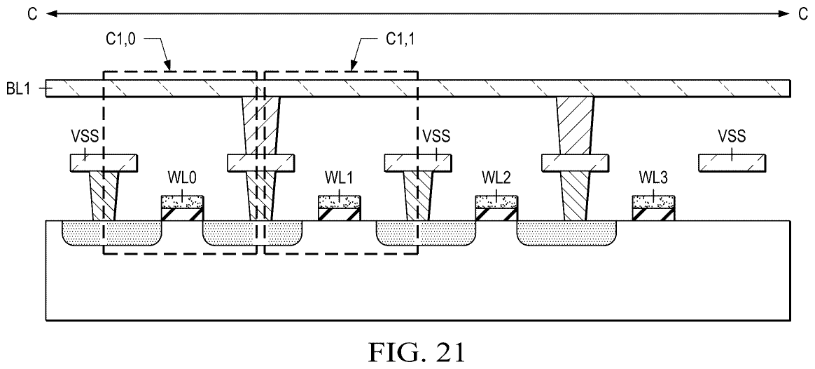

FIG. 19 provides a schematic for another ROM device. FIG. 20 provides a layout that is consistent with FIG. 19's ROM device, and FIG. 21 provides a cross-sectional view consistent with FIG. 20's layout. In FIGS. 19-21, each ROM cell again includes an access transistor, although the access transistor may be lacking some structural features, and stores either a “0” bit or a “1” bit. For cells that store a “0” bit, their access transistors have a source terminal coupled to VSS. See e.g., cells C_{0,0} and C_{0,1}. In contrast, for cells that store a “1” it, their access transistors have a drain terminal that is floating and “disconnected” from the corresponding bit-line of the column. See e.g., cells C_{1,1} and C_{2,0}. In FIGS. 19-21, this “disconnection” can achieved several different ways. For some cells, this “disconnection” can be achieved by omitting a contact in the layout (see cell C2,0 where the left contact to VSS is missing and cells C3,0 and C3,1 where all contacts are missing). For other cells, this “disconnection” can be achieved by altering/shortening a doped region of a source drain so as lengthen a channel region under the gate so even when the gate is activated, the source/drain regions of the access transistor are still isolated from one another (see cells C1,1, C2,0, C3,0, and C3,1).

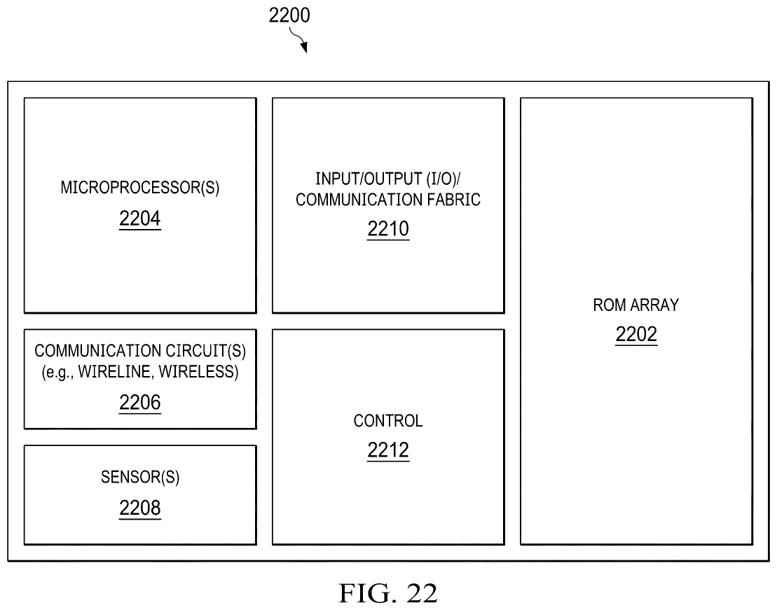

FIG. 22 illustrates a system 2200 in accordance with some examples of the present disclosure. The system can include multiple circuits including a ROM array 2202 that are disposed on a single die, in a packaged integrated circuit, on a circuit board, or otherwise coupled. The system 2200 includes a microprocessor(s) 2204 coupled to the ROM array 2202. The ROM array 2202 can be ROM devices as illustrated and/or described in the present disclosure, and can be operably coupled to the microprocessor(s) 2204. The system also includes communication circuit(s) 2206, such as a wireless and/or wireline circuit, and/or sensor(s) 2208 coupled to the microprocessor(s) 2204 and/or to the ROM array 2202. An input/output (I/O) communication fabric 2210 can include an interconnect structure including metal layers and vias over a substrate of a die, bond pads, wire bonds, solder bumps, or conductive traces on a printed circuit board, multi-bit bus structures, electrical cabling, optical waveguides, optical cables, or wireless transmission medium, can allow the components of the system to communicate with one another. A control circuit 2212 can aid in managing the other components of the system 2200.

Example embodiments of the present disclosure are summarized here. Other embodiments can also be understood from the entirety of the specification and the claims filed herein.

Example 1 relates to a method. In this method, a first photomask is used set to form a first read-only memory (ROM) on a first substrate so as to store a first bit in the first ROM. The first photomask set includes a first metal mask used to form a first set of conductive features in a metal layer at a first layer level relative to the first substrate. A second photomask set is used to form a second ROM on a second substrate so as to store a second bit differing from the first bit in the second ROM. The second photomask set includes a second metal mask used to form a second set of conductive features in a metal layer at the first layer level relative to the second substrate. The second set of conductive features is formed by the second metal mask and differs from the first set of conductive features formed by the first metal mask. The difference between the first set of conductive features formed by the first metal mask and the second set of conductive features formed by second metal mask is solely responsible for the difference between the first bit stored in the first ROM and the second bit stored in the second ROM.

Example 2. In some further examples of example 1, the first photomask set includes: a first active area photomask, a first gate photomask, and a first contact mask, in addition to the first metal mask; and the second photomask set includes: the first active area photomask, the first gate photomask, and the first contact mask, in addition to the second metal mask. Thus, the first active area photomask, the first gate photomask, the first active area photomask, and the first contact mask are used to form the first ROM and the second ROM.

Example 3 relates to a plurality of integrated circuits. These integrated circuits include a first read-only memory (ROM) on a first substrate, and a second ROM on a second substrate. The first ROM stores a first pattern of bits, and the second ROM stores a second pattern of bits that differs from the first pattern of bits. The first ROM includes a first pattern of active area regions, a first pattern of gate electrodes, a first pattern of contacts, and a first pattern of conductive features in a metal layer. The second ROM includes a second pattern of active area regions, a second pattern of gate electrodes, a second pattern of contacts, and a second pattern of conductive features in a metal layer. The first pattern of active area regions is the same as the second pattern of active area regions, the first pattern of gate electrodes is the same as the second pattern of gate electrodes, the first pattern of contacts is the same as the second pattern of contacts, and the first pattern of conductive features in the metal layer over the first substrate differs from the second pattern of conductive features in the metal layer over the second substrate.

In some further examples of example 3, the difference between the first pattern of conductive features in the metal layer over the first substrate and the second pattern of conductive features in the metal layer over the second substrate corresponds to the difference between the first pattern of bits stored in the first ROM and the second pattern of bits stored in the second ROM.

Example 5 relates to a system including an array of read only memory (ROM) cells in which the ROM cells are arranged in rows that each extend in a first direction and columns that each extend in a second direction over a substrate. The rows and the columns intersect one another at respective intersection locations and each intersection location includes a ROM cell. Each ROM cell includes an access transistor having a first terminal, a second terminal, and a gate terminal. A plurality of contacts are disposed within the array of ROM cells, wherein each first terminal and each second terminal of each access transistor includes a contact coupled thereto; and a metal layer is disposed over the plurality of contacts and includes a plurality of reference line structures and a plurality of bit-line structures that extend generally in the second direction over the array of ROM cells. Each of the plurality of reference line structures is coupled to a corresponding contact of the plurality of contacts and each of the plurality of bit-line structures of the metal layer is coupled to a corresponding contact of the plurality of contacts.

In some further examples of example 5 which are referred to as example 6, the plurality of reference line structures and the plurality of bit-line structures of the metal layer are in contact with all contacts of the plurality of contacts over the entire array of ROM cells.

In some further examples of example 5 or example 6, which are referred to as example 7, the plurality of reference line structures and the plurality of bit-line structures of the metal layer are in contact with all contacts of the plurality of contacts except for one or more contacts that correspond to three or more consecutive ROM cells which are included in a column and which each have a first data state and/or for one or more contacts on an outermost edge of the array of ROM cells.

In some further examples of examples 5, 6, or 7, which are referred to as example 8, the plurality of reference line structures of the metal layer comprise a first main reference line extending in the second direction; and a plurality of fingers branching off the first main reference line and extending in the first direction to couple to respective contacts.

In some further examples of examples 5, 6, 7, or 8, which are referred to as example 9, the plurality of bit-line structures of the metal layer include: a first main bit-line extending in the second direction; and a plurality of fingers branching off the first main bit-line and extending in the first direction to couple to respective contacts.

In some further examples of examples 5, 6, 7, 8, or 9, which are referred to as example 10, the ROM cells are each configured to store a first digital bit or a second digital bit, and each ROM cell that stores the first digital bit has an access transistor whose first terminal and second terminal are both coupled to the first main reference line or are both coupled to the first main bit-line.

In some further examples of examples 5, 6, 7, 8, 9, or 10, which are referred to as example 11, the ROM cells are each configured to store a first digital bit or a second digital bit, and each ROM cell that stores the second digital bit has an access transistor whose first terminal is coupled to the first main reference line and second terminal is coupled to the first main bit-line or whose first terminal is coupled to the first main bit-line and second terminal is coupled to the first main reference line.

In some further examples of examples 5, 6, 7, 8, 9, 10, or 11, which are referred to as example 12, the ROM cells are each configured to store a first digital bit or a second digital bit, and a ROM cell that stores the first digital bit has an access transistor whose first terminal and a second terminal are both coupled to the first main reference line.

In some further examples of examples 5, 6, 7, 8, 9, 10, 11, or 12, which are referred to as example 13, the system further includes a plurality of word-lines extending in the first direction and along respective rows of ROM cells. The plurality of word-lines are coupled to gate terminals of the ROM cells.

In some further examples of examples 5, 6, 7, 8, 9, 10, 11, 12, or 13, which are referred to as example 14, the system further includes a processor coupled to the array of ROM cells.

In some further examples of examples 5, 6, 7, 8, 9, 10, 11, 12, 13 or 14, which are referred to as example 15, the system further includes a communication circuit or a sensor coupled to the array of ROM cells.

Example 16 relates to a system. The system includes an array of read only memory (ROM) cells in which the ROM cells are arranged in rows each extending in a first direction and columns each extending in a second direction over a substrate. The rows and the columns intersect one another at respective intersection locations and each intersection location includes a ROM cell of the array. Each ROM cell includes an access transistor having a first terminal, a second terminal, and a control terminal. A plurality of word-lines extend along the respective rows, wherein a word-line associated with a row of ROM cells is coupled to the control terminals of the access transistors of the row of ROM cells. A plurality of bit-lines extend along the respective columns. A reference line extends along a first column of ROM cells and is arranged between nearest neighboring bit-lines. The first column of ROM cells stores a first digital state in a first ROM cell and a second digital state in a second ROM cell. The access transistor of the first ROM cell includes a first terminal and a second terminal both coupled to the reference line or both coupled to a first bit-line of the plurality of bit-lines.

In some further examples of example 16, which are referred to as example 17, the reference line includes a main reference line extending in the second direction, and a plurality of fingers branching off the main reference line and extending in the first direction to couple the fingers to both the first terminal and the second terminal of the access transistor of the first ROM cell; or the first bit-line includes a first main bit-line extending in the second direction, and a plurality of fingers branching off the first main bit-line and extending in the first direction to couple the fingers of the first bit-line to both the first terminal and the second terminal of the access transistor of the first ROM cell.

In some further examples of examples 16 or 17, which are referred to as example 18, the access transistor of the second ROM cell includes a first terminal coupled to the reference line and a second terminal coupled to the first bit-line, or the transistor of the second ROM cell includes the first terminal coupled to the first bit-line and the second terminal coupled to the reference line.

In some further examples of examples 16, 17, or 18, which are referred to as example 19, the reference line includes a main reference line extending in the second direction, and a plurality of fingers branching off the main reference line and extending in the first direction to couple to the first terminal or the second terminal of the access transistor of the second ROM cell. The first bit-line includes a first main bit-line extending in the second direction, and a plurality of fingers branching off the first main bit-line and extending in the first direction to couple the fingers of the first bit-line to second terminal or the first terminal of the access transistor of the second ROM cell.

In some further examples of examples 16, 17, 18, or 19, which are referred to as example 20, the plurality of bit-lines and the reference voltage line are arranged in a metal1 layer over the substrate.

The methods are illustrated and described above as a series of acts or events, but the illustrated ordering of such acts or events is not limiting. For example, some acts or events may occur in different orders and/or concurrently with other acts or events apart from those illustrated and/or described herein. Also, some illustrated acts or events are optional to implement one or more aspects or embodiments of this description. Further, one or more of the acts or events depicted herein may be performed in one or more separate acts and/or phases. In some embodiments, the methods described above may be implemented in a computer readable medium using instructions stored in a memory.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors are illustrated and/or described herein, other transistors (or equivalent switching devices) may be used instead with little or no change to the remaining circuitry. For example, a metal-oxide-silicon FET (“MOSFET”) (such as an n-channel MOSFET, nMOSFET, or a p-channel MOSFET, pMOSFET), a bipolar junction transistor (BJT e.g. NPN or PNP), insulated gate bipolar transistors (IGBTs), and/or junction field effect transistor (JFET) may be used in place of or in conjunction with the devices described herein. The transistors may be depletion mode devices, drain-extended devices, enhancement mode devices, natural transistors or other type of device structure transistors. Furthermore, the devices may be implemented in/over a silicon substrate (Si), a silicon carbide substrate (SiC), a gallium nitride substrate (GaN) or a gallium arsenide substrate (GaAs).

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means +/-10 percent of the stated value, or, if the value is zero, a reasonable range of values around zero. Modifications are possible in the described examples, and other implementations are possible, within the scope of the claims.

What is claimed:

1. A method, comprising:
using a first photomask set to form a first read-only memory (ROM) on a first substrate so as to store a first bit in the first ROM, the first photomask set including a first metal mask used to form a first set of conductive features in a metal layer at a first layer level relative to the first substrate; and
using a second photomask set to form a second ROM on a second substrate so as to store a second bit differing from the first bit in the second ROM, the second photomask set including a second metal mask used to form a second set of conductive features in a metal layer at the first layer level relative to the second substrate, and the second set of conductive features formed by the second metal mask differing from the first set of conductive features formed by the first metal mask,
wherein the difference between the first set of conductive features formed by the first metal mask and the second set of conductive features formed by second metal mask is solely responsible for the difference between the first bit stored in the first ROM and the second bit stored in the second ROM.

2. The method of claim 1:
wherein the first photomask set comprises: a first active area photomask, a first gate photomask, and a first contact mask, in addition to the first metal mask, and
wherein the second photomask set comprises: the first active area photomask, the first gate photomask, and the first contact mask, in addition to the second metal mask, such that the first active area photomask, the first gate photomask, the first active area photomask, and the first contact mask are used to form the first ROM and the second ROM.

3. A plurality of integrated circuits, comprising:
a first read-only memory (ROM) on a first substrate, the first ROM storing a first pattern of bits, the first ROM including a first pattern of active area regions, a first pattern of gate electrodes, a first pattern of contacts, and a first pattern of conductive features in a metal layer; and
a second ROM on a second substrate, the second ROM storing a second pattern of bits that differs from the first pattern of bits, the second ROM including a second pattern of active area regions, a second pattern of gate electrodes, a second pattern of contacts, and a second pattern of conductive features in a metal layer,
wherein the first pattern of active area regions is the same as the second pattern of active area regions, the first pattern of gate electrodes is the same as the second pattern of gate electrodes, the first pattern of contacts is the same as the second pattern of contacts, and the first pattern of conductive features in the metal layer over the first substrate differs from the second pattern of conductive features in the metal layer over the second substrate.

4. The plurality of integrated circuits of claim 3, wherein a difference between the first pattern of conductive features in the metal layer over the first substrate and the second pattern of conductive features in the metal layer over the second substrate corresponds to the difference between the first pattern of bits stored in the first ROM and the second pattern of bits stored in the second ROM.

5. A system, comprising:
an array of read only memory (ROM) cells in which the ROM cells are arranged in rows that each extend in a first direction and columns that each extend in a second direction over a substrate, wherein the rows and the columns intersect one another at respective intersection locations and each intersection location includes a ROM cell, each ROM cell including an access transistor having a first terminal, a second terminal, and a gate terminal;
a plurality of contacts within the array of ROM cells, wherein each first terminal and each second terminal of each access transistor includes a contact coupled thereto; and
a metal layer disposed over the plurality of contacts and including a plurality of reference line structures and a plurality of bit-line structures that extend generally in the second direction over the array of ROM cells, wherein each of the plurality of reference line structures is coupled to a corresponding contact of the plurality of contacts and each of the plurality of bit-line structures of the metal layer is coupled to a corresponding contact of the plurality of contacts.

6. The system of claim 5, wherein the plurality of reference line structures and the plurality of bit-line structures of the metal layer are in contact with all contacts of the plurality of contacts over the entire array of ROM cells.

7. The system of claim 5, wherein the plurality of reference line structures and the plurality of bit-line structures of the metal layer are in contact with all contacts of the plurality of contacts except for one or more contacts that correspond to three or more consecutive ROM cells which are included in a column and which each have a first data state and/or for one or more contacts on an outermost edge of the array of ROM cells.

8. The system of claim 5, wherein the plurality of reference line structures of the metal layer comprise:
a first main reference line extending in the second direction; and
a plurality of fingers branching off the first main reference line and extending in the first direction to couple to respective contacts.

9. The system of claim 8, wherein the plurality of bit-line structures of the metal layer comprise:
a first main bit-line extending in the second direction; and
a plurality of fingers branching off the first main bit-line and extending in the first direction to couple to respective contacts.

10. The system of claim 9, wherein the ROM cells are each configured to store a first digital bit or a second digital bit, and wherein each ROM cell that stores the first digital bit has an access transistor whose first terminal and second terminal are both coupled to the first main reference line or are both coupled to the first main bit-line.

11. The system of claim 9, wherein the ROM cells are each configured to store a first digital bit or a second digital bit, and wherein each ROM cell that stores the second digital bit has an access transistor whose first terminal is coupled to the first main reference line and second terminal is coupled to the first main bit-line or whose first terminal is coupled to the first main bit-line and second terminal is coupled to the first main reference line.

12. The system of claim 9, wherein the ROM cells are each configured to store a first digital bit or a second digital bit, and wherein a ROM cell that stores the first digital bit has an access transistor whose first terminal and a second terminal are both coupled to the first main reference line.

13. The system of claim 5, further comprising
a plurality of word-lines extending in the first direction and along respective rows of ROM cells, the plurality of word-lines coupled to gate terminals of the ROM cells.

14. The system of claim 5, further comprising:
a processor coupled to the array of ROM cells.

15. The system of claim 5, further comprising:
a communication circuit or a sensor coupled to the array of ROM cells.

16. A system, comprising:
an array of read only memory (ROM) cells in which the ROM cells are arranged in rows each extending in a first direction and columns each extending in a second direction over a substrate, wherein the rows and the columns intersect one another at respective intersection locations and each intersection location includes a ROM cell of the array, each ROM cell including an access transistor having a first terminal, a second terminal, and a control terminal;
a plurality of word-lines extending along the respective rows, wherein a word-line associated with a row of ROM cells is coupled to the control terminals of the access transistors of the row of ROM cells;
a plurality of bit-lines extending along the respective columns;
a reference line extending along a first column of ROM cells and arranged between nearest neighboring bit-lines; and
wherein the first column of ROM cells stores a first digital state in a first ROM cell and a second digital state in a second ROM cell, and wherein the access transistor of the first ROM cell includes a first terminal and a second terminal both coupled to the reference line or both coupled to a first bit-line of the plurality of bit-lines.

17. The system of claim 16,
wherein the reference line includes a main reference line extending in the second direction, and a first finger and a second finger that branch off the main reference line and that extend in the first direction, wherein the first finger of the reference line is coupled to the first terminal of the access transistor of the first ROM cell and the second finger of the reference line is coupled to the second terminal of the access transistor of the first ROM cell; or
wherein the first bit-line includes a first main bit-line extending in the second direction, and a first finger and a second finger that branch off the first main bit-line and extend in the first direction, wherein the first finger of the first bit-line is coupled to the first terminal of the access transistor of the first ROM cell and the second finger of the first bit-line is coupled to the second terminal of the access transistor of the first ROM cell.

18. The system of claim 16, wherein the access transistor of the second ROM cell includes a first terminal coupled to the reference line and a second terminal coupled to the first bit-line, or wherein the transistor of the second ROM cell includes the first terminal coupled to the first bit-line and the second terminal coupled to the reference line.

19. The system of claim 18,
wherein the reference line includes a main reference line extending in the second direction, and a plurality of fingers branching off the main reference line and extending in the first direction to couple to the first terminal or the second terminal of the access transistor of the second ROM cell; or
wherein the first bit-line includes a first main bit-line extending in the second direction, and a plurality of fingers branching off the first main bit-line and extending in the first direction to couple the plurality of fingers of the first bit-line to second terminal or the first terminal of the access transistor of the second ROM cell.

20. The system of claim 16, wherein the plurality of bit-lines and the reference line are arranged in a metal1 layer over the substrate.
